(19) United States
(12) Patent Application Publication
(10) Pub. No.: US 2011/0116225 A1
(43) Pub. Date: May 19, 2011

(54) SPOT-COOLING FOR AN ELECTRONIC DEVICE

(76) Inventors: Paul R. Staben, Houston, TX (US); David A. Moore, Tomball, TX (US); Wade D. Vinson, Magnolia, TX (US); Robert Martinez, Houston, TX (US)

(21) Appl. No.: 13/054,061

(22) PCT Filed: Jul. 24, 2008
(86) PCT No.: PCT/US2008/071054

§ 371 Date: Jan. 13, 2011

(51) Int. Cl. G06F 1/20; H05K 7/20

(52) U.S. Cl. 361/679.46; 361/691

(57) ABSTRACT

In at least some embodiments, an apparatus includes a pressurized air source and a tube coupled to the pressurized air source. The apparatus also includes an electronic component that is spot-cooled by moving air between the pressurized air source and the electronic component via the tube.

### BACKGROUND

Electrical devices include numerous components that draw electrical current to perform their intended functions. For example, a computer's microprocessor or central processing unit (“CPU”) requires electrical current to perform many functions such as controlling the overall operations of the computer system and performing various numerical calculations. Generally, any electrical device through which electrical current flows produces heat. The amount of heat any one device generates generally is a function of the amount of current flowing through the device.

Typically, an electrical device is designed to operate correctly within a predetermined temperature range. If the temperature exceeds the predetermined range (i.e., the device becomes too hot or too cold), the device may not function correctly, thereby potentially degrading the overall performance of the computer system. Thus, many electrical devices include cooling systems to regulate the temperature of their electrical components. One type of cooling system is a forced air system that relies on one or more fans to move air over the electronic components in order to cool the components. In some electrical devices, forced air systems do not effectively cool all electrical components (e.g., due to airflow obstacles, positioning and spacing issues, or other factors). Improved techniques for cooling electrical devices are desirable.

### BRIEF DESCRIPTION OF THE DRAWINGS

For a detailed description of exemplary embodiments of the invention, reference will now be made to the accompanying drawings in which:

FIGS. 1A-1C show various spot-cooling systems in accordance with embodiments of the disclosure;

FIGS. 2A-2B show alternative spot-cooling systems in accordance with embodiments of the disclosure;

FIG. 3 shows a socket for a printed circuit board (PCB) module in accordance with embodiments of the disclosure;

FIG. 4 shows an electronic device in accordance with embodiments of the disclosure; and

FIG. 5 shows a method in accordance with embodiments of the disclosure.

### NOTATION AND NOMENCLATURE

Certain terms are used throughout the following description and claims to refer to particular system components. As one skilled in the art will appreciate, computer companies may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . .” Also, the term “couple” or “couples” is intended to mean either an indirect, direct, optical or wireless electrical connection. Thus, if a first device couples to a second device, that connection may be through a direct electrical connection, through an indirect electrical connection via other devices and connections, through an optical electrical connection, or through a wireless electrical connection.

### DETAILED DESCRIPTION

The following discussion is directed to various embodiments of the invention. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

Embodiments of the disclosure are directed to electronic devices, which implement a tube-based spot-cooling system. As used herein, a “tube” refers to any air conduit capable of moving air between a pressurized air source and a location near an electronic device to be cooled. Suitable tubes may be flexible or rigid and may be made from various materials including metal or plastic. The tubes described herein are generally separate from, but may be attached to, the structure formed by a device's frame or chassis. Although no particular tube size is required, suitable tube sizes may range, for example, between 1/16″ to ½″.

In at least some embodiments, the pressurized air source provides positive air pressure (i.e., the tube moves air away from the pressurized air source and towards an electronic component). In alternative embodiments, the pressurized air source provides negative air pressure (i.e., the tube moves air away from the electronic component and towards the pressurized air source). As an example, the output of an air compressor could provide a positive air pressure and the intake of an air compressor could provide a negative air pressure. Also, fans can produce positive and negative air pressures.

In various embodiments, the tube provides direct air movement or indirect air movement. As an example of direct air movement, the tube may directly emit air out of or draw air into a tube opening near the electronic component to be cooled. As an example of indirect air movement, the tube may couple to a socket associated with the electronic component to be cooled. The tube may indirectly emit air out of or draw air into a tube opening via the socket of the electronic component to be cooled. The tube-based spot-cooling system can be used as either a stand-alone cooling system or a supplemental cooling system.

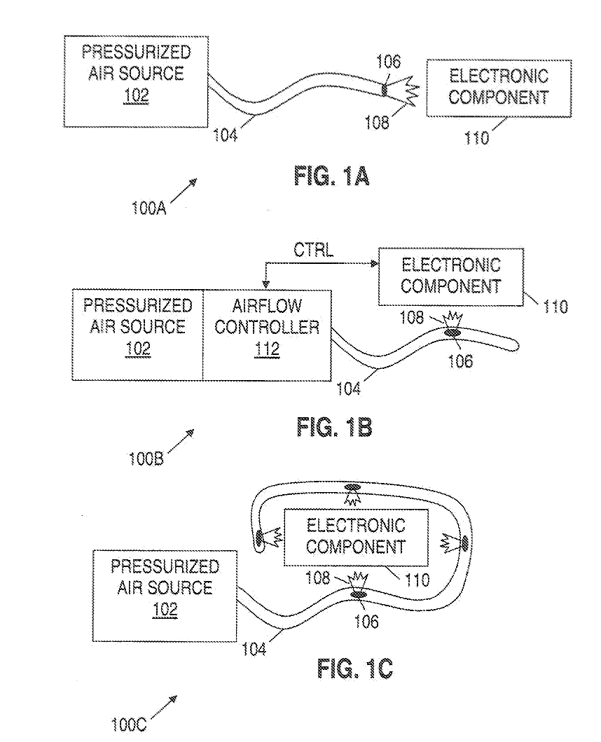

FIGS. 1A-1C show various spot-cooling systems in accordance with embodiments. In FIG. 1A, the spot-cooling system 100A comprises a pressurized air source 102 (e.g., an air compressor) that moves air 108 to or from an electronic component 110 via a tube 104. The air 108 is emitted from or drawn into an opening 106 of the tube 104 to cool the electronic component 110. In FIG. 1A, the opening 106 is at the end of the tube 104.

In FIG. 1B, a spot-cooling system 100B is shown comprising a pressurized air source 102 as well as an airflow controller 112 that controls the timing and/or the amount of air 108 moved through the tube 104. The airflow controller 112 may be part of the pressurized air source 102 or may be separate from the pressurized air source 102. For example, if separate, part of the tube 104 or another tube may conduct air between the pressurized air source 102 and the airflow controller 112.

In at least some embodiments, the airflow controller 112 operates based on a control signal (“CTRL”) received from the electronic component 110. For example, CTRL may indicate a temperature of the electronic component 110, a current flow through the electronic component 110, or another suitable control signal. If CTRL is greater than a predetermined threshold (indicative of, for example, a high temperature condition), the airflow controller 112 permits or otherwise increases the flow of air 108 between the pressurized air source 102 and the electronic component 110 via the tube 104. If CTRL is less than or equal to the predetermined threshold, the airflow controller 112 prevents or otherwise decreases the flow of air between the pressurized air source 102 and the electronic component 110 via the tube 104. As shown in FIG. 1B, the opening 106 that emits or draws the air 108 may be along the tube 104 rather than at the end of the tube 104. The size, shape, and placement of such openings 106 may vary for different embodiments.

In FIG. 1C, a spot-cooling system 100C is shown comprising a pressurized air source 102 and a tube 104 that wraps at least partially around the electronic component 110. Further, multiple openings 106 are provided so that different areas or surfaces of electronic component 110 are cooled by air 108 emitted from or drawn into the tube 104. The size, shape, quantity and placement of the openings 106 may vary for different embodiments. Further, in some embodiments, an airflow controller 112 as described for FIG. 1B may be employed to selectively control the timing and/or the amount of airflow through the tube 104.

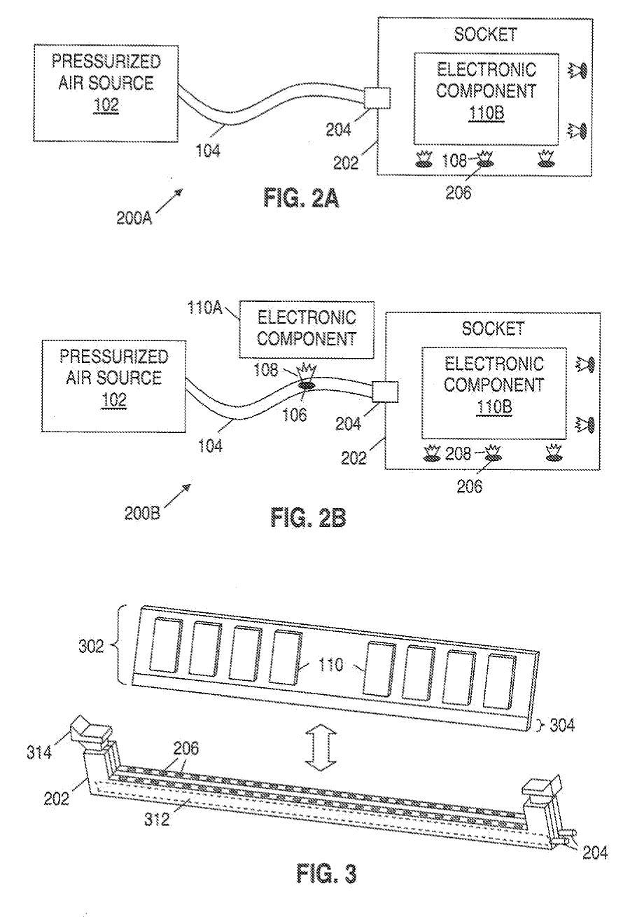

FIGS. 2A-2B show alternative spot-cooling systems in accordance with embodiments of the disclosure. In FIGS. 2A-2B, a socket 202 couples to the tube 104 via a suitable air connector 204 and moves air 108 between an electronic component 110B and the pressurized air source 102 via at least one opening 206. In some embodiments, the connection 204 avoids/prevents air leakage. Alternatively, the air connector 204 may permit some air leakage as long as sufficient air moves to or from the electronic component 110B to cool the electronic component 110B. In FIG. 2B, an opening 106 in the tube 104 also emits or draws air 108 near another electronic component 110A. In other words, in various embodiments, at least one electronic component 110A is cooled by direct air movement via the tube 104 while at least one other electronic component 110B is cooled by indirect air movement via the tube 104 (e.g., via a socket 202 coupled to the tube 104). Although not shown in FIGS. 2A-2B, an airflow controller 112 as described for FIG. 1B may be employed to selectively control the timing and/or the amount of airflow through the tube 104 and socket 202.

In alternative embodiments, any component (not just sockets) having an airflow channel and openings can be connected to the tube for indirect air movement via the tube 104. However, because sockets are already a part of many electronic devices, the layout of components within an electronic device need not be disturbed to accommodate a socket-based spot-cooling technique as described herein. Further, a small pressurized air source (e.g., an air compressor) would be sufficient for the spot-cooling technique in many embodiments.

FIG. 3 shows a socket 202 for a printed circuit board (PCB) module 302 in accordance with embodiments of the disclosure. As shown, the socket 202 comprises at least one air connector 204 and openings 206 as described previously for FIGS. 2A-2B. At least one airflow channel 312 moves air between the connectors 204 and the openings 206. Further, the socket 202 comprises at least one latch 314 that enables the PCB module 302 to be fastened into and released from the socket 202. The socket 202 also comprises electrically conductive contacts (now shown), which line up with a plurality of conductive contacts 304 of the PCB module 302. In this manner, when the PCB module 302 is inserted into the socket 202, the electrical components 110 mounted on the PCB module 302 are able to communicate with external components (not on the PCB module 302) through the socket 202.

In FIG. 3 the socket 202 is representative of a memory module socket (e.g., for DIMM memory) having a suitable airflow channel 312 and openings 206. In different embodiments, the layout of a memory module sockets may vary (e.g., air connectors 204, airflow channels 312 and openings 206 may vary with respect to size, shape, and location). Other examples of sockets which may be modified or designed to distribute air include, but are not limited to, graphics card sockets, processor sockets (e.g., CPU or GPU sockets), general purpose expansion bus sockets (e.g., PCI or PCI express card sockets), LED light mountings (e.g., display backlights), Application Specific Integrated Circuit (ASIC) sockets and/or battery sockets.

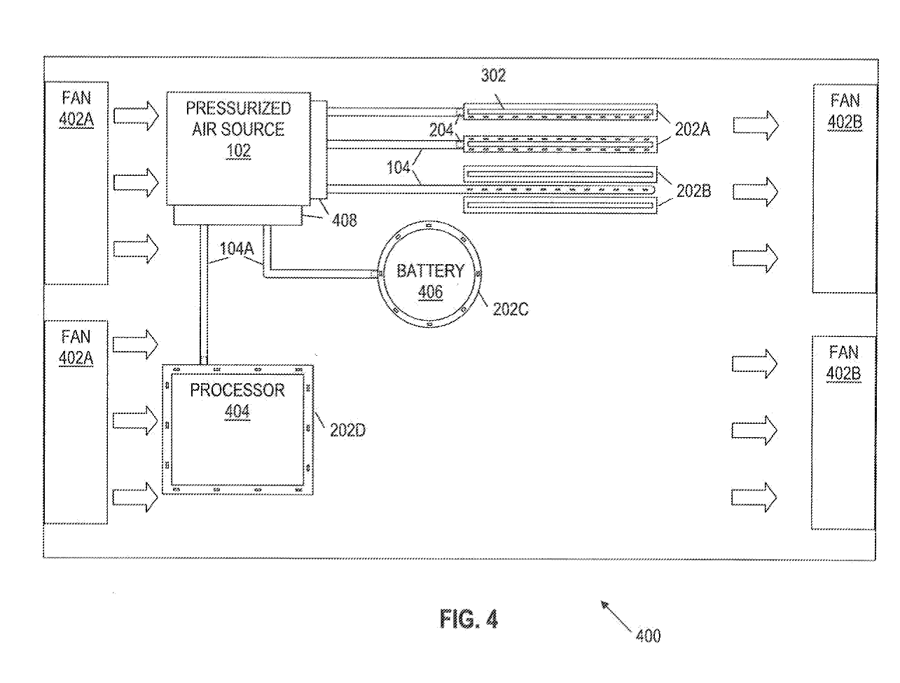

FIG. 4 shows an electronic device 400 in accordance with embodiments of the disclosure. The electronic device 400 is representative of a desktop computer, a laptop computer, a server, or some other electronic devices that benefits from spot-cooling at described herein. In FIG. 4, the electronic device 400 comprises a pressurized air source 102 and tubes 104 as previously described. The tubes 104 connect to various sockets 202 via suitable connectors 204. Specifically, a PCB module socket 202A emits or draws air to cool a PCB module 302. Further, a battery socket 202C emits or draws air to cool a battery 406. Further, a processor socket 202D emits or draws air to cool a processor 404.

In FIG. 4, various tubes expel air indirectly (via the sockets 202A, 202C, 202D) while one of the tubes (between the sockets 202B) expels air directly. Although not shown in FIG. 4, an airflow controller 112 as described for FIG. 1B may be employed to selectively control the flow of air near some or all of the electronic components of the device 400 (i.e., the processor 404, the battery 406, or the PCB modules 302). In various embodiments, the device 400 includes additional or fewer electronic components which benefit from the spot-cooling techniques described herein.

In the embodiment of FIG. 4, the spot-cooling provided by moving air to or from the tubes or sockets supplements another cooling system. For example, fans 402A may push air into and/or fans 402B may pull air out of the device 400 to cool the various electronic components. Although the fans 402A and 4026 are shown at the edges of the device 400, the location, size and cooling effect provided by fans or other air movers may vary. Regardless of the fan location, the spot-cooling described herein can improve cooling in the device 400 by pushing stagnant air away from components or obstacles (e.g., PCB modules) and into the airflow provided by the fans 402A or 402B. As previously mentioned, the spot-cooling described herein may alternatively be a stand-alone cooling technique (i.e., the fans 402 are omitted).

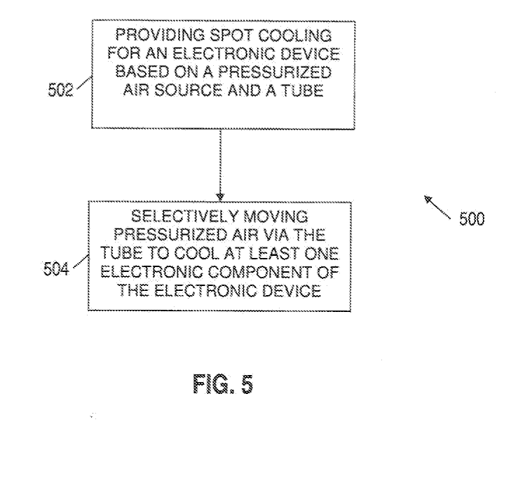

FIG. 5 shows a method 500 in accordance with embodiments. The method 500 comprises providing spot-cooling for an electronic device based on a pressurized air source and a tube (block 502). The method 500 further comprises selectively moving pressurized air via the tube to cool at least one electronic component of the electronic device (block 504). In at least some embodiments, the method 500 further comprises steps such as drawing air into the tube to cool the at least one electronic component. Alternatively, the method 500 further comprises emitting air from the tube to cool the at least one electronic component. Further, in at least some embodiments, the method 500 comprises moving air via a socket coupled to the tube, the socket being associated with the at least one electronic component. Further, in at least some embodiments, the method 500 comprises placing the tube and tube opening between adjacent PCB modules (or electronic components) to move stagnant air between the PCB modules and/or identifying a stagnant air area in an electronic device and placing the tube and tube opening in the stagnant air area to move stagnant air.

The above discussion is meant to be illustrative of the principles and various embodiments of the present invention. Numerous variations and modifications will become apparent to those skilled in the art once the above disclosure is fully appreciated. For example, refrigerated air can be used in the spot-cooling system described herein. In such case, condensation issues would need to be properly handled. It is intended that the following claims be interpreted to embrace all such variations and modifications.

What is claimed is:

1. An apparatus, comprising:
a pressurized air source;
a tube coupled to the pressurized air source; and
an electronic component, wherein the electronic device is spot-cooled by moving air between the pressurized air source and the electronic component via the tube.

2. The apparatus of claim 1 further comprising a socket coupled to the tube, wherein the electronic component is spot-cooled by moving air through the socket.

3. The apparatus of claim 2 wherein the socket comprises at least one airflow channel and a plurality of openings to move air through the socket.

4. The apparatus of claim 2 wherein the socket supports a printed circuit board (PCB) module having the at least one electronic component mounted thereon.

5. The apparatus of claim 1 wherein the pressurized air source provides a positive air pressure that causes air to be emitted from the tube.

6. The apparatus of claim 1 wherein the pressurized air source provides a negative air pressure that causes air to be drawn into the tube.

7. The apparatus of claim 1 further comprising an airflow controller to selectively control airflow via the tube based on a control signal.

8. The apparatus of claim 1 wherein the apparatus is a computer.

9. The apparatus of claim 1 wherein the tube comprises a plurality of tube openings that provide spot-cooling to the electronic component.

10. The apparatus of claim 9 wherein the tube openings extend at least partially around the electronic component.

11. The apparatus of claim 1 wherein the tube comprises a first tube opening for spot-cooling the electronic component and a second tube opening for spot-cooling another electronic component.

12. A computer system, comprising:
a pressurized air source; and
a socket coupled to the pressurized air source, the socket being associated an electronic component,
wherein the socket moves air between the pressurized air source and the electronic component to cool the electronic component.

13. The computer system of claim 12 wherein the socket is compatible with a processor.

14. The computer system of claim 12 wherein the socket is compatible with a printed circuit board (PCB) module.

15. The computer system of claim 12 further comprising a tube, wherein the tube has a first tube opening connected to the socket and a second tube opening to directly cool another electronic component.
